(19) United States
(12) Patent Application Publication
(10) Pub. No.: US 2014/0272346 A1
(43) Pub. Date: Sep. 18, 2014

(54) METHOD OF GROWING ALUMINUM OXIDE ONTO SUBSTRATES BY USE OF AN ALUMINUM SOURCE IN AN OXYGEN ENVIRONMENT TO CREATE TRANSPARENT, SCRATCH RESISTANT WINDOWS

(71) Applicant: Rubicon Technology, Inc., Bensenville, IL (US)

(72) Inventors: Jonathan LEVINE, Chicago, IL (US); John P. CIRALDO, Elgin, IL (US)

(73) Assignee: Rubicon Technology, Inc., Bensenville, IL (US)

(21) Appl. No.: 14/101,980

(22) Filed: Dec. 10, 2013

Related U.S. Application Data
(60) Provisional application No. 61/790,786, filed on Mar. 15, 2013.

(51) Int. Cl. C23C 16/40; C03C 17/245

(52) U.S. Cl. CPC C23C 16/403; C03C 17/245
USPC 428/213; 428/702; 428/432; 428/701; 428/220; 428/336; 118/728; 118/725; 118/696; 427/248.1

(57) ABSTRACT

A system and process for inter alia coating a substrate such as glass with a layer of aluminum oxide to create a scratch-resistant and shatter-resistant matrix comprised of a thin scratch-resistant aluminum oxide film deposited on one or more sides of a transparent and shatter-resistant substrate for use in consumer and mobile devices such as watch crystals, cell phones, tablet computers, personal computers and the like. The system and process may include a reactive thermal evaporation technique. An advantage of the reactive thermal evaporation technique includes using arbitrarily high oxygen pressures, allowing for higher growth rates of aluminum oxide at the surface of the substrate and, ultimately, a less expensive process. Another advantage of this reactive thermal evaporation process is that it does not utilize electrical fields typically found in traditional reactive sputtering techniques.

### CROSS-REFERENCE TO RELATED APPLICATIONS

This application claims benefit and priority to U.S. Provisional Application No. 61/790,786 filed on Mar. 15, 2013, the disclosure of which is incorporated by reference herein in its entirety.

### BACKGROUND OF THE INVENTION

1.0 Field of the Disclosure

The present disclosure relates to a system, a method, and a device for inter alia coating a material (such as, e.g., a substrate) with a layer of aluminum oxide to provide a transparent, scratch-resistant surface.

2.0 Related Art

There are many applications for use of glass including applications in, e.g., the electronics area. Several mobile devices such as, e.g., cell phones and computers may employ glass screens that may be configured as a touch screen. These glass screens can be prone to breakage or scratching. Some mobile devices use hardened glass such as ion exchange glass, to reduce surface scratching or the likelihood of cracking.

However, an even harder and more scratch-resistant surface would be an improvement over the currently available materials. A harder surface over what is currently known and available would reduce the likelihood even more of scratching and cracking. Reducing scratching and cracking tendencies would provide longer life products. Moreover, a reduction in the incidents of accelerated loss of useful life of various glass-based products would be advantageous; especially those products that are handled frequently by users and prone to accidental dropping.

Currently, there are no known products employing film aluminum oxide on glass or other transparent substrates. A method for the Chemical Vapor Deposition growth aluminum oxide has been demonstrated but is, like full sapphire windows, far too cost prohibitive. Ion-exchange glass is a hardened glass that is used in many mobile devices to reduce surface scratches and the likelihood of cracking the screen. However, even this product may be prone to breaking and scratching.

Traditional sputtering techniques often present issues for growing aluminum oxide, such as, e.g., the use of an oxygen environment in a chamber may have a tendency to parasitically oxidize the aluminum. To minimize such issues, manufacturers may use a lower oxygen pressure. A problem with using a lower pressure, however, is that it may negatively affect the growth rate or the quality of the deposited film.

A process and composition that provides improved characteristics that gives better performance, e.g., better resistance to cracking and scratching, at lower costs would be beneficial.

### SUMMARY OF THE DISCLOSURE

According to one non-limiting example of the disclosure, a system, a method, and a device are provided to inter alia coat a material (such as, e.g., a substrate) with a layer of aluminum oxide to provide an improved transparent, scratch-resistant surface.

In one aspect, a system for creating a scratch-resistant and shatter-resistant matrix is provided that includes a chamber to create a partial pressure of oxygen, a device to support or secure a transparent substrate within the chamber and a device to release energetic and unbounded aluminum atoms into the chamber creating a deposition beam to react with the oxygen to create an aluminum oxide film on a surface of the transparent substrate.

In one aspect, a process for creating an aluminum oxide enhanced substrate, the process comprising the steps of exposing a transparent shatter-resistant substrate to aluminum atoms and/or aluminum oxide molecules to create a scratch-resistant and shatter-resistant matrix comprising a thin scratch-resistant aluminum oxide film deposited on one or more sides of the transparent and shatter-resistant substrate and stopping the exposing based on a predetermined parameter producing a hardened transparent shatter-resistant substrate for resisting breakage or scratching.

In one aspect, a process for creating aluminum oxide enhanced substrate is provided; the process comprising the steps of creating a partial pressure of oxygen in both parts of a chamber configured with a first part and a second part, providing energetic and unbounded aluminum atoms in the first part, providing protection for a target transparent shatter-resistant substrate located in the second part of the chamber to protect the target shatter-resistant transparent substrate from the aluminum atoms and/or aluminum oxide molecules, removing the protection when a predetermined stable partial pressure is achieved exposing the target transparent substrate to the aluminum atoms and/or aluminum oxide molecules to create a scratch-resistant and shatter-resistant matrix comprising a thin scratch-resistant aluminum oxide film deposited on one or more sides of a transparent and shatter-resistant substrate, wherein the thin scratch-resistant aluminum oxide film is less than 1% of a thickness of the target transparent shatter-resistant substrate and stopping the exposing based on a predetermined parameter, providing a hardened transparent shatter-resistant substrate for improving breakage or scratch resistance characteristics.

In one aspect, a substrate is provided comprising a transparent shatter-resistant substrate and an aluminum oxide film deposited on the transparent shatter-resistant substrate, wherein the transparent shatter-resistant substrate and the deposited aluminum oxide film creates a matrix providing a transparent shatter-resistant window resistant to breakage or scratching. The transparent shatter-resistant substrate may comprise one of: a boron silicate glass, an aluminum-silicate glass, an ion-exchange glass, quartz, yttria-stabilized zirconia (YSZ) and a transparent plastic. In one aspect, the resulting window may have a thickness of about 2 mm, or less, and the window has a shatter resistance with a Young's Modulus value that is less than that of sapphire, being less than about 350 gigapascals (GPa). In one aspect, the deposited aluminum oxide film may have a thickness less than about 1% of a thickness of the transparent or translucent shatter-resistant substrate. In one aspect, the deposited aluminum oxide film may have a thickness between about 10 nm and 5 microns.

In one aspect, a window is provided comprising a transparent shatter-resistant media and an aluminum oxide film deposited on the transparent shatter-resistant media, wherein the transparent shatter-resistant media and the deposited aluminum oxide film creates a matrix providing a transparent shatter-resistant window resistant to breakage or scratching, wherein the resulting window has a thickness of about 2 mm, or less, and the transparent shatter-resistant window has a shatter resistance with a Young's Modulus value that is less than that of sapphire, that is less than about 350 gigapascals (GPa).

Additional features, advantages, and examples of the disclosure may be set forth or apparent from consideration of the detailed description, drawings and attachment. Moreover, it is to be understood that the foregoing summary of the disclosure and the following detailed description and drawings are exemplary and intended to provide further explanation without limiting the scope of the disclosure as claimed.

### BRIEF DESCRIPTION OF THE DRAWINGS

The accompanying drawings, which are included to provide a further understanding of the disclosure, are incorporated in and constitute a part of this specification, illustrate examples of the disclosure and together with the detailed description serve to explain the principles of the disclosure. No attempt is made to show structural details of the disclosure in more detail than may be necessary for a fundamental understanding of the disclosure and the various ways in which it may be practiced. In the drawings:

FIG. 1 is a block diagram of an example of a system to perform reactive thermal evaporation, configured according to principles of the disclosure;

FIG. 2 is a block diagram of an example of a system to perform reactive thermal evaporation, configured according to principles of the disclosure; and

FIG. 3 is a flow diagram of an example process for creating an aluminum oxide enhanced substrate, the process performed according to principles of the disclosure.

The present disclosure is further described in the detailed description that follows.

### DETAILED DESCRIPTION OF THE DISCLOSURE

The disclosure and the various features and advantageous details thereof are explained more fully with reference to the non-limiting that are described and/or illustrated in the accompanying drawings and detailed in the following description. It should be noted that the features illustrated in the drawings are not necessarily drawn to scale, and features of one embodiment may be employed with other embodiments as the skilled artisan would recognize, even if not explicitly stated herein. Descriptions of well-known components and processing techniques may be omitted so as to not unnecessarily obscure the embodiments of the disclosure. The examples used herein are intended merely to facilitate an understanding of ways in which the disclosure may be practiced and to further enable those of skill in the art to practice the embodiments of the disclosure. Accordingly, the examples and embodiments herein should not be construed as limiting the scope of the disclosure. Moreover, it is noted that like reference numerals represent similar parts throughout the several views of the drawings.

The terms “including”, “comprising,” and variations thereof, as used in this disclosure, mean “including, but not limited to”, unless expressly specified otherwise.

The terms “a”, “an”, and “the”, as used in this disclosure, mean “one or more”, unless expressly specified otherwise.

Devices that are in communication with each other need not be in continuous communication with each other, unless expressly specified otherwise. In addition, devices that are in communication with each other may communicate directly or indirectly through one or more intermediaries.

Although process steps, method steps, algorithms, or the like, may be described in a sequential order, such processes, methods and algorithms may be configured to work in alternate orders. In other words, any sequence or order of steps that may be described does not necessarily indicate a requirement that the steps be performed in that order. The steps of the processes, methods or algorithms described herein may be performed in any order practical. Further, some steps may be performed simultaneously. In some applications, not all steps may be required.

When a single device or article is described herein, it will be readily apparent that more than one device or article may be used in place of a single device or article. Similarly, where more than one device or article is described herein, it will be readily apparent that a single device or article may be used in place of the more than one device or article. The functionality or the features of a device may be alternatively embodied by one or more other devices which are not explicitly described as having such functionality or features.

Reactive thermal evaporation performed according to principles of the disclosure offers an advantage and improvement over prior known methods including reactive sputtering, as explained in the examples below. Moreover, the use of aluminum oxide films, as opposed to full sapphire windows, provides additional cost savings by eliminating the need to cut, grind, or polish sapphire, which is difficult and costly.

According to an aspect of the disclosure, a transparent and shatter-resistant substrate 120, such as, e.g., glass, quartz, or the like, may be placed onto a stage 110 which may be heated within an evacuated chamber 102. Process gas(es) are permitted to flow into the evacuation chamber 102 such that a controlled partial pressure is achieved. These gases may contain oxygen either in atomic or molecular form, and may also contain inert gases such as argon. Upon achieving the desired partial pressure, a deposition beam of aluminum atoms 115, may be introduced such that the substrate 120 is exposed to the beam of aluminum atoms 115. The deposition beam 115 may be a cloud-like beam. A matrix comprising an aluminum oxide layer 121 coating and the transparent and shatter-resistant substrate 120 is produced through a reactive thermal evaporation deposition, performed according to principles of the disclosure. According to principles of this disclosure, a deposition layer(s) several nanometers to several hundred microns thick can be achieved depending on the process parameters and duration. Process duration can be several minutes to several hours. By controlling the aluminum atom flux and oxygen partial pressure, the properties of the coated film can be tailored to maximize the films scratch resistance

FIG. 1 is a block diagram of an example of a system 200 configured to perform reactive thermal evaporation, the system 200 configured according to principles of the disclosure. The system 200 may be used to coat a material (such as, e.g., a substrate 120, which may be glass, quartz, transparent plastic, or the like) with a layer 121 of aluminum oxide, according to principles of the disclosure. The system 200 may be employed to produce a very hard and superior scratch-resistant surface on glass, or other substrates. For example, the system 200 may be used to transform a material such as soda-lime glass, borosilicate glass, ion exchange glass, alumina-silicate glass, yttria-stabilized zirconia (YSZ), transparent plastic, or other shatter-resistant transparent window material into a matrix comprising the shatter-resistant bulk window with a scratch-resistant applied aluminum oxide coating resulting in a superior product for use in applications where a hard, break-resistant, scratch-resistant surface is beneficial. Such applications may include, e.g., consumer devices, optical lenses, watch crystals, electronic devices or scientific instruments, and the like.

A benefit provided by the resultant matrix surface 121 of this disclosure includes superior mechanical performance, such as, e.g., improved scratch resistance, greater resistance to cracking compared to currently used materials such as traditional untreated glass, plastic, etc. Additionally, by using aluminum oxide coated on a substrate such as glass, rather than an entire sapphire window (i.e., a window comprising all sapphire), the cost may be reduced substantially, making the product available for widespread consumer usage.

As shown in FIG. 1, system 200 may include an evacuation chamber 102 with partial pressure of process gas 135 created therewithin, including molecular or atomic oxygen. The system may include a stage 110, a process gas inlet 125, and a gas exhaust 130. The stage 110 may be configured to be heated (or cooled) by a heat source 123. The stage 110 may be configured to move in any one or more dimensions of 3-D space, including configured to be rotatable, movable in a x-axis, movable in a y-axis and/or movable in a z-axis.

A substrate 120 may be placed on the stage 110. The substrate 120 may be a planar material or a non-planar material. The substrate 120 may have one or more surfaces that may be subject to treatment. The substrate may be soda-lime glass, borosilicate glass, ion exchange glass, aluminosilicate glass, yttria-stabilized zirconia (YSZ), transparent plastic, or other shatter-resistant transparent window material. In some applications, the substrate 120 may be embodied in multiple dimensions, e.g., to include surfaces oriented in three dimensions that may be treated by the matrix creating process.

The system 200 for performing a reactive thermal evaporation process may include a crucible 106 containing substantially pure aluminum 107 that may be heated to the point that the aluminum 107 begins to evaporate. The aluminum 107 may be used to create energized aluminum atoms for producing a controlled beam 115 of aluminum atoms and/or aluminum oxide molecules. Adjusting an orientation or position of the substrate 120 relative to the deposition beam 115 may adjust an exposure amount of the energetic aluminum atoms and aluminum oxide molecules to the substrate 120. This may also permit coating of the aluminum oxide to select or additional sections of the substrate 120.

The system 200 may include a partition 140 that may be configured with an aperture or shutter 145 that is configured to open and close. The partition 140 may create two parts within the chamber; a first part 136 and a second part 137. The first part 136 may include the substantially pure aluminum 107. The second part 137 may include the stage 110 and substrate 120. The partition 140 is configured to create two separate sections 136, 137 that prevent the energetic aluminum atoms and aluminum oxide molecules of the first part 136 from prematurely accessing the second part 137. The substrate 120 may be separated from the aluminum 107 while the aluminum 107 is being heated during the first stage of the process by partition 140 and a closed shutter 145. The partition 140 and closed shutter 145 prevent aluminum 107 vapors and/or aluminum oxide vapors from reaching the substrate 120 prematurely. Once sufficient temperature for the aluminum 107 has been reached (for example, about 1350° Celsius), oxygen may be permitted to flow from the gas inlet 125 into the evacuation chamber 102 (i.e., into both parts 136 and 137), where a partial pressure 135 may be achieved. This gas may contain oxygen either in atomic or molecular form, and may also contain inert gases such as argon.

Upon achieving a predetermined stable oxygen partial pressure 135, the shutter 145 may be opened, exposing the substrate 120 to the beam of energetic and unbounded aluminum atoms 115 (which might include some aluminum oxide molecules) in the presence of oxygen. The gases including energetic aluminum atoms and/or aluminum oxide molecules 115 of the first part 136 may then access the second part 137. The shutter 145 may be opened approximately when the stable oxygen partial pressure 135 has been achieved, but may vary. Typically, the pressurized environment of oxygen is created before or proximate to opening the shutter 145. The oxygen and aluminum react, forming aluminum oxide on or near the substrate 120 creating and growing an aluminum oxide film 121 at the surface 122 as described previously. Gas from the process may exhaust through the gas exhaust 130.

An advantage of reactive thermal evaporation technique includes heating the aluminum 107 without oxygen being present initially, so that the substantially pure aluminum 107 does not oxidize prematurely. Thus, using the reactive thermal evaporation technique, a manufacturer of, e.g., sapphire enhanced glass or other enhanced substrates, may use arbitrarily high oxygen pressures, allowing for higher growth rates of aluminum oxide at the surface 122 of the substrate 120 and, ultimately, a less expensive process. Another advantage of this reactive thermal evaporation process is that it does not utilize electrical fields typically found in traditional reactive sputtering techniques. A traditional reactive sputtering method may require a complex chamber design that uses high frequency electrical fields to deal with charging effects that arise as a result of aluminum oxide's high electrical resistance. By utilizing the reactive thermal evaporation process of this present disclosure, no electrical fields are required, eliminating charging issues and ultimately simplifying the process.

The substrate 120 may be exposed to the beam of aluminum atoms and/or aluminum oxide molecules 115, and the exposure stopped based on a predetermined parameter such as, e.g., a predetermined time period and/or a predetermined depth of layering of aluminum oxide on the substrate being achieved.

Being exposed to oxygen within the evacuation chamber 102, the aluminum atoms 115 may form aluminum oxide (Al₂O₃) molecules, which adhere to the substrate surface 122 forming a matrix comprising a scratch-resistant aluminum oxide film 121 that is in contact with and is coating at least one substrate surface 122. If the beam 115 is not sufficiently large enough to homogeneously cover the top substrate surface 122, the substrate 120 itself may be moved within the deposition beam 115, such as, e.g., through movement of the stage 110 which may be controlled to move up, down, left, right, and/or rotate, to allow an even coating. In some implementations, the crucible 106 with aluminum 107 may be moved to change orientation of the deposition beam 115.

Moreover, the substrate 120 may be heated (or cooled) by device 123 sufficiently to allow mobility of aluminum and aluminum oxide particles on the surface 122 of the substrate 120, allowing for improved quality of the matrix generation. The deposited film 121 formed at the surface 122 of the substrate chemically and/or mechanically adheres to the substrate surface 122 which creates a bond sufficiently strong enough to prevent delamination of the aluminum oxide (Al₂O₃) with the substrate 120, creating a hard and strong surface 120 that is highly resistant to breaking and/or scratching. The deposited film 121 is conformal to the surface 122 of the substrate 120. This may be useful to coat irregular or non-planar surfaces. This tends to result in a superior bond over, for example, laminate type techniques.

The growth rate of the aluminum oxide (Al₂O₃) deposited film 121 at the surface 122 may be tunable. The growth rate of the aluminum oxide (Al₂O₃) film layer 121 may be enhanced by reducing the distance between the aluminum 107 and the substrate 120. This may be achieved, for example, by moving the crucible 106 and/or moving the stage 110. The rate may be further enhanced by modification of the temperature of the source aluminum 107, thereby altering the flux of aluminum and aluminum oxide vapors; or by modifying the flow of oxygen into the chamber 102. Other techniques of modifying the growth rate may include altering the ambient pressure within the chamber 102, or by other techniques of altering the growth environment.

The substrate 120 may be exposed to the deposition beam 115, and the exposure stopped based on a predetermined parameter such as, e.g., a predetermined time period and/or a predetermined depth of layering of aluminum oxide on the substrate being achieved. In one aspect, the predetermined depth may be a thickness of aluminum oxide film layer 121 of less than about 1% of the thickness of the substrate. In one aspect, the thickness of the deposited aluminum oxide film layer may be between about 10 nm and about 5 microns. In one aspect, the thickness of the deposited aluminum oxide film layer 121 may be less than about 10 microns.

A matrix comprising a scratch-resistant surface layer several nanometers to several hundred microns thick grown atop a transparent and shatter-resistant substrate can be achieved depending on the process parameters and duration. Process duration can be several minutes to several hours. By controlling the flux of aluminum atoms and/or aluminum oxide molecules and oxygen partial pressure, the properties of the matrix formed at the surface 122 can be tailored to maximize the scratch resistance.

FIG. 2 is a block diagram of an example of a system 201 configured to perform reactive thermal evaporation, the system 201 configured according to principles of the disclosure. The system 201 is similar to the system 200 of FIG. 1, except that the orientation of the substrate 120 and the substantially pure aluminum 107 may be oriented differently. A securing device 126 may be used to secure the substrate 120 so that the substrate is above the substantially pure aluminum 107. The aluminum atom and/or aluminum oxide beam 115 may be projected upwardly towards the substrate 120. In general, any suitable orientation of the substrate 120 in relation to the substantially pure aluminum 107 and/or beam 115 may be employed. The securing mechanism 126 may be movable in any one or more axis. The securing mechanism 126 may also be configured with a device 123 to heat (or cool) the substrate 120.

In some implementations, the system 200 and 201 may include a computer 205 to control the operations of the various components of the systems 200 and 201. For example, a computer 205 may control the heating of the aluminum 107. The computer 205 may also control the device 123 to control heating (or cooling) of the substrate 120. A computer may also control the motion of the stage 110, the securing mechanism 126 and may control the partial pressures of the evacuation chamber 102. The computer 205 may also control the tuning of the gap/distance between the aluminum 107 and the substrate 120. The computer 205 may control the amount of exposure duration of the deposition beam 115 with the substrate 120, perhaps based on, e.g., a predetermined parameter(s) such as time, or based on a depth of the aluminum oxide formed on the substrate 120, or amount/level of oxygen pressure employed, or any combination therefore. The gas inlet 125 and gas outlet 130 may include valves (not shown) for controlling the movement of the gases through the systems 200 and 201. The valves may be controlled by the computer 205. The computer 205 may include a database for storage of process control parameters and programming.

FIG. 3 is a flow diagram of an example process for creating an aluminum oxide enhanced substrate, the process performed according to principles of the disclosure. The process of FIG. 3 may be a type of reactive thermal evaporation, and can be used in conjunction with the systems 200, 201. At step 305 a chamber, e.g. chamber 102, may be provided that is configured to permit a partial pressure to be created therein, and configured to permit a target substrate 120 such as, e.g., glass, borosilicate glass, aluminosilicate glass, ion-exchange glass, transparent plastic, or yttria-stabilized zirconia (YSZ) to be coated. Further, the chamber 102 may be configured to permit separation of the target substrate 120 from the aluminum 107 while the aluminum 107 is being heated, and configured to remove the separation during the process as describe below. At step 310, a source of aluminum such as, e.g., substantially pure aluminum, may be provided that enables energetic and unbounded aluminum atoms to be generated in the chamber 102. At step 315, a securing device (e.g., securing device 126) or stage (e.g., stage 110) may be configured within the chamber 102. Both the stage 110 and/or securing device 126 may be configured to be rotatable. The stage 110 and/or securing device 126 may be configured to be moved in a x-axis, a y-axis and/or a z-axis.

At step 320, a protective barrier may be provided so that the target substrate, e.g., substrate 120, can be temporally protected from the beam of aluminum atoms and aluminum oxide molecules when created within the chamber. The protection may be a partition 140 that may be configured with, e.g., an aperture or shutter 145 that is configured to open in a first position and close in a second position. In the closed position, the aperture or shutter 145 separates a first part of the chamber, e.g., first part 136, from a second part, e.g., second part 137. The first part 136 may include the aluminum 107. The second part 137 may include the stage 110 or securing mechanism 126, and the target substrate 120.

At step 325, a target substrate 120 such as, e.g. glass, borosilicate glass, aluminosilicate glass, ion-exchange glass, transparent plastic, or YSZ, having one or more surfaces to be coated may be provided on the stage 110 or secured by securing mechanism 126, in the second part 137 of the chamber 102. At optional step 330, the target substrate 120 may be heated. At step 335, the substantially pure aluminum may be heated to produce aluminum atoms and/or aluminum oxide in the first part 136 of the chamber 102. The aluminum atoms may create a deposition beam 115 directed towards the partition 140. At step 340, a partial pressure of oxygen may be created in both parts 136 and 137 of the chamber. This may be achieved by permitting oxygen to flow into the chamber 102, perhaps under pressure. At step 345, the protection may be removed. This may be accomplished by opening the shutter 145 in partition 140. This permits the aluminum atoms and/or aluminum oxide of beam 115 to reach the target substrate 120, which may form a beam 115. The deposited film may be formed at the surface(s) of the target substrate 120. Further, the aluminum atoms may interact with the oxygen environment as they are directed towards the substrate 120 creating aluminum oxide molecules which are also be directed toward the substrate 120.

At optional step 350 the gap or distance between the aluminum 107 source and the substrate 120 may be adjusted, typically reduced but may be increased, to control the rate of depositing of the aluminum oxide film on the target substrate 120. At optional step 355, the substrate 120 may be re-positioned by adjusting the stage 110 orientation. The stage 110 may be rotated or moved in any axis. At step 360, a thin film is permitted to be created at one or more surfaces 122 of the substrate 120 as the aluminum atoms and/or aluminum oxide molecules coat and bond with the one or more surfaces 122. The process may be terminated when one or more predetermined parameter(s) are achieved such as time, or based on a depth of the aluminum oxide formed on the substrate 120, or amount/level of oxygen pressure employed, or any combination therefore. Moreover, a user may stop the process at any time.

This reactive thermal evaporation process of FIG. 3 has an advantage in that it does not utilize or require electrical fields and subsequent complexities typically found in traditional techniques such as reactive sputtering techniques.

The steps of FIG. 3 may be performed by or controlled by a computer, e.g., computer 205 that is configured with software programming to perform the respective steps. FIG. 3 may also represent a block diagram of the components for executing the steps thereof. The components may include software executable by a computer processor (e.g., computer 205) for reading the software from a physical storage (a non-transitory medium) and executing the software that is configured to performing the respective steps. The computer processor may be configured to accept user inputs to permit manual operations of the various steps described.

The process of FIG. 3 and the systems of FIGS. 1 and 2 may produce a matrix comprising a thin, transparent, and shatter-resistant window (i.e., the substrate 120) coated with a scratch-resistant aluminum oxide film 121 that is lightweight, has superior resistance to breakability and has a thickness of about 2 mm or less. The thin window (i.e., the matrix combination of the deposited scratch-resistant aluminum oxide film and transparent and shatter-resistant substrate) is configured and characterized as having a shatter resistance with a Young's Modulus value that is less than that of sapphire, i.e., less than about 350 gigapascals (GPa).

Moreover, it should be understood that, in the case that there are different values for the Young's Modulus based on a testing method or region of material tested (e.g., ion-exchange glass which may have different values for the surface and the bulk), that the lowest value is the applicable value. The thin window produced by the process of FIG. 3 may be used to produce thin windows for use in different devices including, e.g., watch crystals, optical lenses, and touch screens as used in, e.g., mobile phones, tablet computers, and laptop computers, where maintaining a scratch-free or break-resistant surface may be of primary importance.

While the disclosure has been described in terms of examples, those skilled in the art will recognize that the disclosure can be practiced with modifications in the spirit and scope of the appended claims. These examples are merely illustrative and are not meant to be an exhaustive list of all possible designs, embodiments, applications or modifications of the disclosure.

What is claimed:

1. A system for creating a scratch-resistant and shatter-resistant matrix, the system comprising:
a chamber to create a partial pressure of oxygen;
a device to support or secure a transparent substrate within the chamber; and
a device to release energetic and unbounded aluminum atoms into the chamber creating a deposition beam to react with the oxygen to create an aluminum oxide film on a surface of the transparent substrate.

2. The system of claim 1, further comprising a mechanism that is configured to close in a first position and open in a second position, and the mechanism configured to separate the transparent substrate from the aluminum atoms and/or aluminum oxide molecules in the first position, and configured to expose the transparent substrate to the aluminum atoms and aluminum oxide molecules in the second position.

3. The system of claim 1, wherein the device to release energetic and unbounded aluminum atoms creates a beam of aluminum atoms and/or aluminum oxide molecules.

4. The system of claim 1, further comprising a heat source to heat the transparent substrate.

5. The system of claim 1, wherein the device to support or secure the transparent substrate is configured to move in at least one direction for positioning the transparent substrate in relation to the deposition beam.

6. The system of claim 5, wherein the device to support or secure the transparent substrate is configured to be rotatable, movable in a x-axis, movable in a y-axis or movable in a z-axis.

7. The system of claim 1, further comprising a computer configured to control at least one of: the partial pressure, the device to support or secure a transparent substrate, and the device to release energetic and unbounded aluminum atoms into the chamber.

8. The system of claim 1, wherein the transparent substrate comprises a borosilicate glass, an aluminosilicate glass, an ion-exchange glass, a transparent plastic, or yttria-stabilized zirconia.

9. A process for creating an aluminum oxide enhanced substrate, the process comprising the steps of:
exposing a transparent shatter-resistant substrate to aluminum atoms and/or aluminum oxide molecules to create a scratch-resistant and shatter-resistant matrix comprising a thin scratch-resistant aluminum oxide film deposited on one or more sides of the transparent and shatter-resistant substrate; and
stopping the exposing based on a predetermined parameter producing a hardened transparent shatter-resistant substrate for resisting breakage or scratching.

10. The process of claim 9, wherein the exposing step includes exposing borosilicate glass, aluminosilicate glass, ion-exchange glass, transparent plastic, or yttria-stabilized zirconia.

11. The process of claim 9, further comprising heating an aluminum source to create the unbounded aluminum atoms.

12. The process of claim 9, wherein the stopping step stops the exposing based on a predetermined parameter.

13. The process of claim 12, wherein the predetermined parameter includes at least one of: a predetermined time period, a predetermined depth of layering of aluminum oxide on the transparent substrate, and a level of oxygen pressure during the exposing.

14. The process of claim 9, further comprising the steps of:
producing energetic and unbounded aluminum atoms; and
creating a pressurized environment of oxygen to create the scratch-resistant and shatter-resistant matrix comprising a scratch-resistant aluminum oxide film deposited on one or more sides of a transparent and shatter-resistant substrate.

15. The process of claim 14, further comprising the step of protecting the transparent substrate from the aluminum source as the aluminum source is being heated.

16. The process of claim 15, further comprising ceasing the protecting to permit the aluminum atoms and/or aluminum oxide molecules to reach the transparent substrate.

17. The process of claim 16, wherein the step of creating a pressurized environment of oxygen is performed before or proximate the ceasing step.

18. The process of claim 9, further comprising adjusting an orientation or position of the transparent substrate relative to the deposition beam to adjust an exposure amount of the aluminum atoms and/or aluminum oxide molecules to the transparent substrate.

19. A device utilizing the hardened transparent substrate produced by the process of claim 9.

20. A process for creating aluminum oxide enhanced substrate, the process comprising the steps of:
creating a partial pressure of oxygen in both parts of a chamber configured with a first part and a second part;
providing energetic and unbounded aluminum atoms in the first part;
providing protection for a target transparent shatter-resistant substrate located in the second part of the chamber to protect the target shatter-resistant transparent substrate from the aluminum atoms and/or aluminum oxide molecules;
removing the protection when a predetermined stable partial pressure is achieved exposing the target transparent substrate to the aluminum atoms and/or aluminum oxide molecules to create a scratch-resistant and shatter-resistant matrix comprising a thin scratch-resistant aluminum oxide film deposited on one or more sides of a transparent and shatter-resistant substrate, wherein the thin scratch-resistant aluminum oxide film is less than 1% of a thickness of the target transparent shatter-resistant substrate; and
stopping the exposing based on a predetermined parameter, providing a hardened transparent shatter-resistant substrate for improving breakage or scratch-resistance characteristics.

21. The process of claim 20, wherein the target substrate comprises borosilicate glass, aluminosilicate glass, ion-exchange glass, transparent plastic or yttria-stabilized zirconia (YSZ).

22. The process of claim 20, wherein the step of providing energetic and unbounded aluminum atoms is provided by heating aluminum.

23. The process of claim 20, wherein the predetermined parameter includes at least one of: a predetermined time period, a predetermined depth of layering of aluminum oxide on the target transparent substrate, and a level of oxygen pressure during the exposing.

24. The process of claim 20, further comprising at least one of the following steps:
adjusting the distance from a source of the energetic and unbounded aluminum atoms and the target transparent substrate; and
adjusting the orientation of the target transparent substrate.

25. A device utilizing the hardened transparent shatter-resistant substrate produced by the process of claim 20.

26. The process of claim 20, wherein the hardened transparent shatter-resistant substrate is about 2 mm or less thick.

27. A substrate comprising:
a transparent shatter-resistant substrate; and
an aluminum oxide film deposited on the transparent shatter-resistant substrate, wherein the transparent shatter-resistant substrate and the deposited aluminum oxide film creates a matrix providing a transparent shatter-resistant window resistant to breakage or scratching.

28. The substrate of claim 27, wherein the transparent shatter-resistant substrate comprises one of: a boron silicate glass, an aluminum-silicate glass, an ion-exchange glass, quartz, yttria-stabilized zirconia (YSZ) and a transparent plastic.

29. The substrate of claim 27, wherein the resulting window has a thickness of about 2 mm, or less, and the window has a shatter resistance with a Young's Modulus value that is less than that of sapphire, being less than about 350 gigapascals (GPa).

30. The substrate of claim 27, wherein the deposited aluminum oxide film has a thickness less than about 1% of a thickness of the transparent or translucent shatter-resistant substrate.

31. The substrate of claim 27, wherein the deposited aluminum oxide film has a thickness between about 10 nm and 5 microns.

32. The substrate of claim 27, wherein the deposited aluminum oxide film has a thickness less than about 10 microns.

33. A device utilizing the substrate of claim 27.

34. A window comprising:
a transparent shatter-resistant media; and
an aluminum oxide film deposited on the transparent shatter-resistant media, wherein the transparent shatter-resistant media and the deposited aluminum oxide film creates a matrix providing a transparent shatter-resistant window resistant to breakage or scratching,
wherein the resulting window has a thickness of about 2 mm, or less, and the transparent shatter-resistant window has a shatter resistance with a Young's Modulus value that is less than that of sapphire, that is less than about 350 gigapascals (GPa).

35. The window of claim 34, wherein the transparent shatter-resistant media comprises one of: a boron silicate glass, an aluminum-silicate glass, an ion-exchange glass, quartz, yttria-stabilized zirconia (YSZ) and a transparent plastic.

36. A device utilizing the window of claim 34.
